(19) United States
(12) Patent Application Publication
(10) Pub. No.: US 2012/0013007 A1
(43) Pub. Date: Jan. 19, 2012

(54) PACKAGE-ON-PACKAGE SEMICONDUCTOR PACKAGE HAVING SPACERS DISPOSED BETWEEN TWO PACKAGE SUBSTRATES

(76) Inventors: Hyun-ik HWANG, Asan-si (KR); Heui-seog KIM, Asan-si (KR); Wha-su SIN, Cheonan-si (KR); Jun-soo HAN, Cheonan-si (KR)

(21) Appl. No.: 13/161,902

(22) Filed: Jun. 16, 2011

(30) Foreign Application Priority Data
Jul. 15, 2010 (KR) 10-2010-0068587

(51) Int. Cl. H01L 23/488

(52) U.S. Cl. 257/738; 257/E23.023

(57) ABSTRACT

A Package-on-Package (POP) semiconductor package has a structure in which a second semiconductor package is stacked on a first semiconductor package. A plurality of spacers are disposed between a first substrate of the first semiconductor package and a second substrate of the second semiconductor package so as to maintain a gap between the first substrate and the second substrate. The plurality of spacers may project from a bottom surface of the second substrate toward the first substrate, or may project from a top surface of the first substrate toward the second substrate. When an upper molding layer is formed on the second substrate so as to cover a second semiconductor chip, the plurality of spacers may be connected to the upper molding layer via through holes that vertically pass through the second substrate. When a first semiconductor chip is adhered to the top surface of the first substrate with an adhering layer, the plurality of spacers may be connected to the adhering layer on the top surface of the first substrate.

### CROSS-REFERENCE TO RELATED APPLICATIONS

This application claims the benefit of priority to Korean Patent Application No. 10-2010-0068587, filed on Jul. 15, 2010, in the Korean Intellectual Property Office, the disclosure of which is incorporated herein in its entirety by reference.

### BACKGROUND

The disclosed embodiments relate to a Package-on-Package (POP) semiconductor package, and more particularly, to a POP semiconductor package having a structure in which spacers are disposed between two package substrates.

Recently, electronic devices have been continuously developed to have a high performance, and have been simultaneously minimized. Accordingly, semiconductor packages used in these electronic devices should also have a high performance and be minimized. In order to satisfy such a need, a Multi-Chip Package (MCP) having several chips mounted thereon, a POP semiconductor package having two or more semiconductor packages stacked thereon, or the like is widely used.

In this regard, a typical POP semiconductor package has a structure in which an upper semiconductor package is stacked on a lower semiconductor package, and a plurality of solder balls are disposed between a substrate of the upper semiconductor package and a substrate of the lower semiconductor package for coupling and electrical connection between the upper semiconductor package and the lower semiconductor package.

However, the POP semiconductor package may bend due to the POP semiconductor package being affected by hardening or heating during or after a manufacturing process. In this case, a gap between the substrate of the upper semiconductor package and the substrate of the lower semiconductor package may become small such that the solder balls disposed therebetween may be deformed, having pressed and wide shapes. When the solder balls are deformed, the solder balls that are adjacent to each other may contact each other such that a short may occur therebetween.

### SUMMARY

According to one embodiment, there is provided a Package-on-Package (POP) semiconductor package including a first semiconductor package comprising a first substrate and a first semiconductor chip that is mounted on the first substrate; a second semiconductor package that is stacked on the first semiconductor package and that comprises a second substrate and a second semiconductor chip mounted on the second substrate; and a plurality of spacers disposed between the first substrate and the second substrate and maintaining a gap between the first substrate and the second substrate. The plurality of spacers are not electrically connected to any circuitry on the first substrate or second substrate.

A plurality of connection pads may be arranged on a bottom surface of the first substrate so as to connect to an external substrate, a plurality of connection pads may be arranged on a top surface of the first substrate and a bottom surface of the second substrate so as to face each other, and a plurality of solder balls may be interposed between the plurality of connection pads of the first substrate and the plurality of connection pads of the second substrate.

The plurality of spacers may project from the bottom surface of the second substrate toward the first substrate.

An upper molding layer may be formed on the second substrate so as to cover the second semiconductor chip, and the plurality of spacers may be connected to the upper molding layer via a plurality of through holes that vertically penetrate the second substrate. The plurality of spacers and the upper molding layer may include an epoxy molding compound (EMC). The plurality of spacers may be disposed to be adjacent to four corners of the second semiconductor chip, respectively.

A plurality of solder bumps may be arranged between the first semiconductor chip and the first substrate of the first semiconductor package to bond and electrically connect the first substrate and the first semiconductor chip.

The first semiconductor chip of the first semiconductor package may be adhered to the first substrate with an adhering layer, a plurality of bonding pads may be arranged on the top surface of the first substrate, and a wire may connect each of the plurality of bonding pads and the first semiconductor chip.

The first semiconductor chip of the first semiconductor package may be adhered on the top surface of the first substrate with an adhering layer; a slit that vertically penetrates the first substrate may be formed in a middle portion of the first substrate; on a bottom surface of the first substrate, a plurality of bonding pads may be arranged along sides of the slit; and the first semiconductor chip may be connected to each of the plurality of bonding pads with a wire that passes through the slit.

The second semiconductor chip of the second semiconductor package may be adhered to the second substrate with an adhering layer, a plurality of bonding pads may be arranged on a top surface of the second substrate, and a wire may connect each of the plurality of bonding pads and the second semiconductor chip.

The second semiconductor chip of the second semiconductor package may be adhered on a top surface of the second substrate with an adhering layer; a slit that vertically penetrates the second substrate may be formed in a middle portion of the second substrate; on the bottom surface of the second substrate, a plurality of bonding pads may be arranged along sides of the slit; and the second semiconductor chip may be connected to each of the plurality of bonding pads with a wire that passes through the slit.

The plurality of spacers may project from a top surface of the first substrate toward the second substrate.

The first semiconductor chip may be adhered to the top surface of the first substrate with an adhering layer, and the plurality of spacers may include the same material as the adhering layer, and are connected to the adhering layer on the top surface of the first substrate. The plurality of spacers and the adhering layer may include an epoxy-based thermocurable adhering material. The plurality of spacers may have a height that is greater than the sum of heights of the adhering layer and the first semiconductor chip. The plurality of spacers may be disposed to be adjacent to four corners of the first semiconductor chip, respectively.

A slit that vertically penetrates the first substrate may be formed in a middle portion of the first substrate; on a bottom surface of the first substrate, a plurality of bonding pads may be arranged along sides of the slit; and the first semiconductor chip and each of the plurality of bonding pads may be connected via a wire that passes through the slit.

The second semiconductor chip may be adhered on a top surface of the second substrate due to an adhering layer; a slit that vertically penetrates the second substrate may be formed in a middle portion of the second substrate; on a bottom surface of the second substrate, a plurality of bonding pads may be arranged along sides of the slit; and the second semiconductor chip may be connected to each of the plurality of bonding pads with a wire that passes through the slit.

The second semiconductor chip may be adhered to a top surface of the second substrate with an adhering layer, a plurality of bonding pads may be arranged on the top surface of the second substrate, and a wire may connect each of the plurality of bonding pads and the second semiconductor chip.

In another embodiment, a Package-on-Package (POP) semiconductor package is disclosed. The POP semiconductor package includes: a first semiconductor package comprising a first substrate and a first semiconductor chip mounted on the first substrate; a second semiconductor package stacked on the first semiconductor package and that comprises a second substrate and a second semiconductor chip mounted on the second substrate; a plurality of balls disposed between the second substrate and the first substrate, the plurality of balls bonding and electrically connecting the first substrate to the second substrate; and a plurality of spacers, separate from the plurality of balls, disposed between the first substrate and the second substrate and contacting both the first substrate and the second substrate.

The plurality of spacers may include a plurality of columnar-shaped spacers extending at least the distance between a first surface of the first substrate and a first surface of the second substrate.

At least one pad may be connected to for each of the plurality of balls, but no pads may be connected to the plurality of spacers. Each of the plurality of spacers may comprise a non-electrically-conductive material. As such, none of the plurality of spacers may be configured to transmit signals to any circuitry.

In one embodiment, an upper molding layer may cover the second substrate and the second semiconductor chip, wherein the upper molding layer is made of the same material as the plurality of spacers.

A plurality of holes may be included in the second substrate, each of the plurality of holes coinciding with a respective spacer of the plurality of spacers, wherein each hole of the plurality of holes is filled with the same material as the plurality of spacers and the upper molding layer. The material may be a non-electrically-conductive material.

In another embodiment, an adhesive layer may connect the first substrate to the first semiconductor chip, wherein the adhesive layer is made of the same material as the plurality of spacers and is connected to the plurality of spacers.

In one embodiment, the first substrate includes first edge and a second edge opposite the first edge, and a first surface extending from the first edge to the second edge in a first direction; a first group of balls of the plurality of balls are disposed on the first surface of the first substrate proximate to the first edge; a second group of balls of the plurality of balls are disposed on the first surface of the first substrate proximate to the second edge; a first group of spacers of the plurality of spacers is disposed such that the first group of balls are between the first edge and the first group of spacers in the first direction; and a second group of spacers of the plurality of spacers is disposed such that the second group of balls are between the second edge and the second group of spacers in the first direction.

### BRIEF DESCRIPTION OF THE DRAWINGS

Exemplary embodiments will be more clearly understood from the following detailed description taken in conjunction with the accompanying drawings in which:

FIGS. 1A and 1B are vertical cross-sectional views illustrating an exemplary structure of a Package-on-Package (POP) semiconductor package according to one embodiment, wherein FIG. 1A illustrates a status before a first semiconductor package and a second semiconductor package are coupled to each other, and FIG. 1B illustrates a status after the first semiconductor package and the second semiconductor package are coupled to each other;

FIG. 2 is an exemplary plane view of the second semiconductor package, which illustrates the disposition of spacers of FIGS. 1A and 1B, according to one exemplary embodiment;

FIG. 3 is a vertical cross-sectional view illustrating a structure of a POP semiconductor package according to another exemplary embodiment;

FIG. 4 is a vertical cross-sectional view illustrating a structure of a POP semiconductor package according to another exemplary embodiment;

FIGS. 5A and 5B are vertical cross-sectional views illustrating a structure of a POP semiconductor package according to another exemplary embodiment, wherein FIG. 5A illustrates a status before a first semiconductor package and a second semiconductor package are coupled to each other, and FIG. 5B illustrates a status after the first semiconductor package and the second semiconductor package are coupled to each other;

FIG. 6 is an exemplary plane view of the first semiconductor package, which illustrates the disposition of spacers of FIGS. 5A and 5B, according to one exemplary embodiment;

FIG. 7 is a vertical cross-sectional view illustrating a structure of a POP semiconductor package according to another exemplary embodiment; and

FIG. 8 depicts a method of manufacturing a POP semiconductor package according to one exemplary embodiment.

### DETAILED DESCRIPTION OF THE EMBODIMENTS

The present disclosure will now be described more fully with reference to the accompanying drawings, in which exemplary embodiments are shown. The disclosed embodiments may, however, be embodied in many different forms and should not be construed as being limited to the embodiments set forth herein.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional or perspective illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an edge or corner region illustrated as having sharp edges may have somewhat rounded or curved features. Likewise, elements illustrated as circular or spherical may be oval in shape or may have certain straight or flattened portions. Thus, the regions illustrated in the figures may be schematic in nature and their shapes are not intended to limit the scope of the disclosed embodiments.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

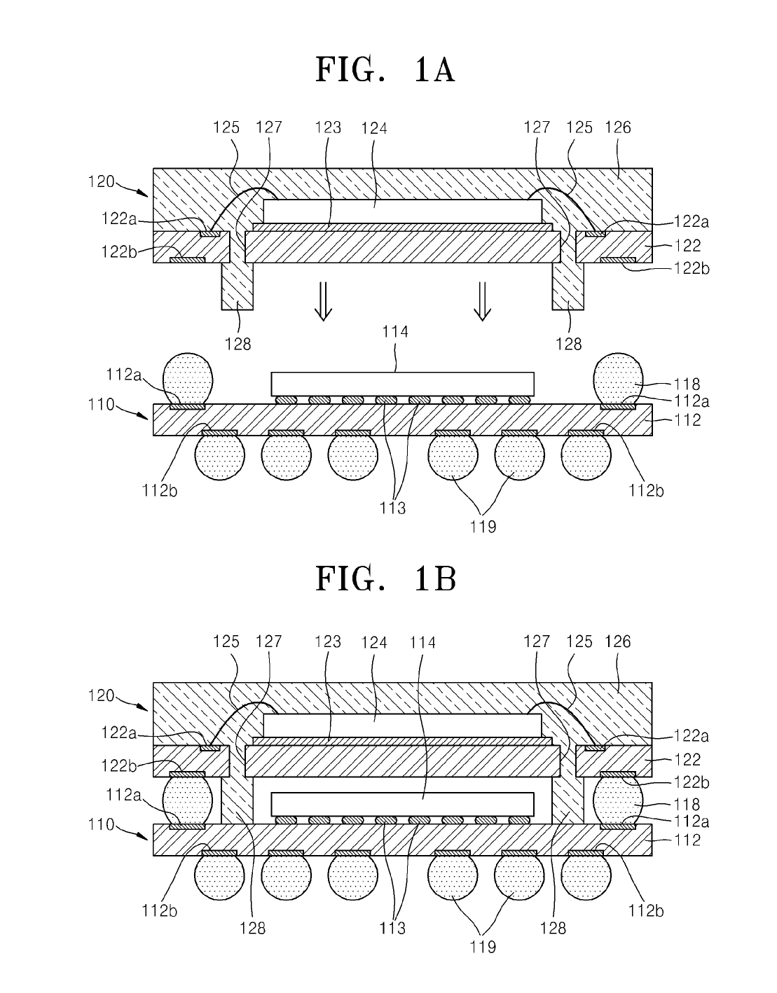

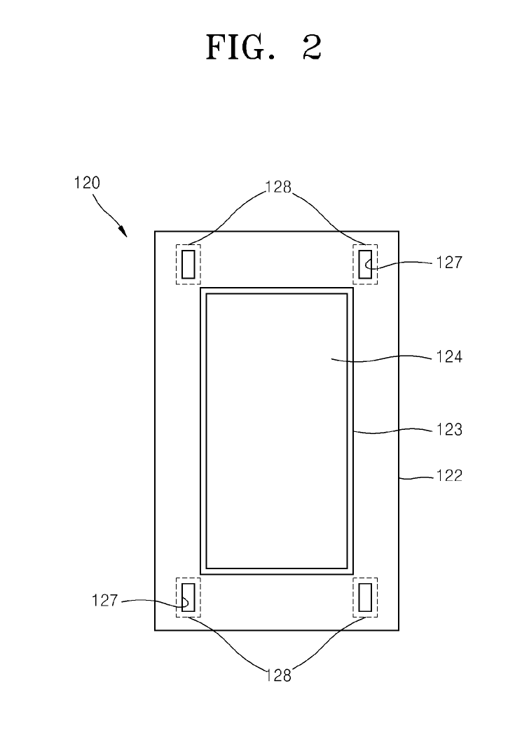

FIGS. 1A and 1B are vertical cross-sectional views illustrating an exemplary structure of a Package-on-Package (POP) semiconductor package according to one embodiment. FIG. 1A illustrates a status before a first semiconductor package 110 and a second semiconductor package 120 are coupled to each other, and FIG. 1B illustrates a status after the first semiconductor package 110 and the second semiconductor package 120 are coupled to each other. FIG. 2 is a plane view of the second semiconductor package 120, which illustrates the disposition of spacers 128 of FIGS. 1A and 1B, according to one exemplary embodiment.

Referring to FIGS. 1A and 1B, the POP semiconductor package according to one embodiment has a structure in which the second semiconductor package 120 is stacked on the first semiconductor package 110. The first semiconductor package 110 includes a first substrate 112, and a first semiconductor chip 114 that is mounted on the first substrate 112. The second semiconductor package 120 includes a second substrate 122, and a second semiconductor chip 124 that is mounted on the second substrate 122. However, the number of chips in each package and the number of packages in the POP semiconductor package are not limited to the exemplary embodiments depicted in FIGS. 1A and 1B. For example, one or more of the first or second semiconductor packages 110 or 120 may include more than one chip in a stacked structure or other arrangement, and additional packages (not shown) may be stacked on the first and second semiconductor packages to comprise the POP semiconductor package.

In the first semiconductor package 110, in one embodiment, the first semiconductor chip 114 may be mounted on the first substrate 112 by a flip chip bonding manner.

In more detail, a plurality of electrodes, such as solder bumps 113, are arranged between the first semiconductor chip 114 and the first substrate 112 to bond and electrically connect the first substrate 112 and the first semiconductor chip 114. A plurality of additional electrodes, such as connection pads 112a, are arranged in a top surface of the first substrate 112 so as to electrically connect to the second semiconductor package 120 via inner solder balls 118 (which in one embodiment can be other types of electrically conductive bumps or electrodes that are not necessary ball-shaped) adhered to the connection pads 112a, respectively. The top surface of the first substrate 112 may extend in a first direction between a first edge and a second opposite edge of the first substrate 112, and the connection pads 112a may be arranged in a single row or rows having a predetermined distance from either edge of the first semiconductor chip 114. A plurality of electrodes, such as connection pads 112b, may be arranged in a bottom surface of the first substrate 112 so as to connect to an external substrate, and outer solder balls 119 (which in one embodiment can be other types of electrically conductive bumps or electrodes that are not necessary ball-shaped) may be adhered to the connection pads 112b, respectively.

In the second semiconductor package 120, in one embodiment, the second semiconductor chip 124 may be mounted on the second substrate 122 by a wire bonding manner. In more detail, the second semiconductor chip 124 may be adhered on the second substrate 122 with an adhering layer 123. A plurality of electrodes, such as bonding pads 122a, are arranged in a top surface of the second substrate 122, and the second substrate 122 may be electrically connected to the second semiconductor chip 124 with a wire 125 that connects the second semiconductor chip 124 and each of the bonding pads 122a. A plurality of electrodes, such as connection pads 122b, are arranged in a bottom surface of the second substrate 122 so as to electrically and physically connect to the first semiconductor package 110 through the inner solder balls 118. The connection pads 122b are arranged facing the connection pads 112a that are arranged in the top surface of the first substrate 112 of the first semiconductor package 110.

In one embodiment, the second semiconductor chip 124, the wire 125, and the bonding pads 122a may be covered and protected by an upper molding layer 126. In one embodiment, the upper molding layer 126 may be formed of a thermocurable resin including an epoxy molding compound (EMC), which is generally used as a semiconductor package molding resin. The upper molding 126 may thus contact and surround the wires 125 and other circuitry and electrodes on the second chip 124 and the second substrate 122, thereby protecting and electrically isolating that circuitry from other elements or devices that may be located near the POP semiconductor package.

In the second semiconductor package 120, the spacers 128 that project may be formed on the bottom surface of the second substrate 122. As will be described later, the spacers 128 function to maintain a gap between the first substrate 112 and the second substrate 122 when the second semiconductor package 120 is coupled on the first semiconductor package 110. Thus, the spacers 128 have a height corresponding to a desired gap between the first substrate 112 and the second substrate 122. In one embodiment, the spacers 128 may have a columnar shape, such as a quadrangular-column shape. However, the spacers 128 may have a circular-column shape or one of various column shapes other than the quadrangular-column shape.

The spacers 128 may be formed of an EMC, which is the same material for forming the upper molding layer 126, and may be connected to the upper molding layer 126 via through holes 127 that are formed vertically penetrating the second substrate 122. In more detail, in one embodiment, to form the spacers 128, cavities corresponding to the spacers 128 are formed in a lower mold, and then the EMC is injected between the lower mold and an upper mold. By doing so, the injected EMC is not only filled in a space between the second substrate 122 and the upper mold but also filled in the cavities, which are formed in the lower mold below the second substrate 122, via the through holes 127 that are formed in the second substrate 122. Thus, the upper molding layer 126 is formed on the second substrate 122, and simultaneously, the spacers 128 that are connected to the upper molding layer 126 may be formed under the second substrate 122.

Referring to FIG. 2, the spacers 128 may be disposed to be adjacent to four corners of the second semiconductor chip 124, respectively. In addition, referring to FIGS. 1A and 1B, in one embodiment, a first group of connection pads connected to a first group of balls are disposed on the top surface of the first substrate proximate to the first edge of the first substrate, and a second group of balls may be disposed on the top surface of the first substrate proximate to the second edge of the first substrate. The spacers 128 may be disposed such that in the POP semiconductor package, the first group of balls are between the first edge and the first group of spacers in a first direction, and a second group of spacers of the plurality of spacers is disposed such that the second group of balls are between the second edge and the second group of spacers in the first direction. That is, to resist deformation of the substrates due to bending, the spacers 128 may be disposed at a location closer to the center of the substrate than where the inner solder balls 118 are disposed.

However, the dispositions of the spacers 128 of FIGS. 1A, 1B, and 2 are exemplary only. That is, the spacers 128 may be disposed at various positions which are appropriate to maintain the gap between the first substrate 112 and the second substrate 122 so as to resist deformation due to a bending of the first semiconductor package 110 and the second semiconductor package 120.

Referring back to FIG. 1B, when the second semiconductor package 120 is coupled to the first semiconductor package 110, the connection pads 122b that are arranged on the bottom surface of the second substrate 122 of the second semiconductor package 120 contact the inner solder balls 118, so that the connection pads 122b are electrically connected to the bonding pads 122a that are arranged on the top surface of the first substrate 112. In this manner, the first semiconductor package 110 and the second semiconductor package 120 are physically coupled and electrically connected to each other by the inner solder balls 118 formed therebetween.

In one embodiment, when the second semiconductor package 120 is coupled to the first semiconductor package 110, the spacers 128 contact the top surface of the first substrate 112 as well as a bottom surface of the second substrate 122, so that the spacers 128 firmly support the first substrate 112 and the second substrate 122 and maintain the gap between the first substrate 112 and the second substrate 122. Because the spacers 128 may be formed of the EMC which is part of upper molding layer 126, in one embodiment the spacers 128 are formed of a non-electrically-conductive material, and the spacers do not electrically connect to (i.e., are not capable of transmitting electrical signals to or from) any circuitry on either of the first or second substrates. Thus, it is possible to prevent the first semiconductor package 110 and the second semiconductor package 120 from being bent as a result of the first semiconductor package 110 and the second semiconductor package 120 being affected by hardening or heating during or after a POP semiconductor package manufacturing process. Therefore, it is possible to prevent the inner solder balls 118, which are disposed between the first substrate 112 and the second substrate 122, from being pressed and then deformed. Consequently, it is possible to prevent a short due to contact between the inner solder balls 118 that are adjacent to each other.

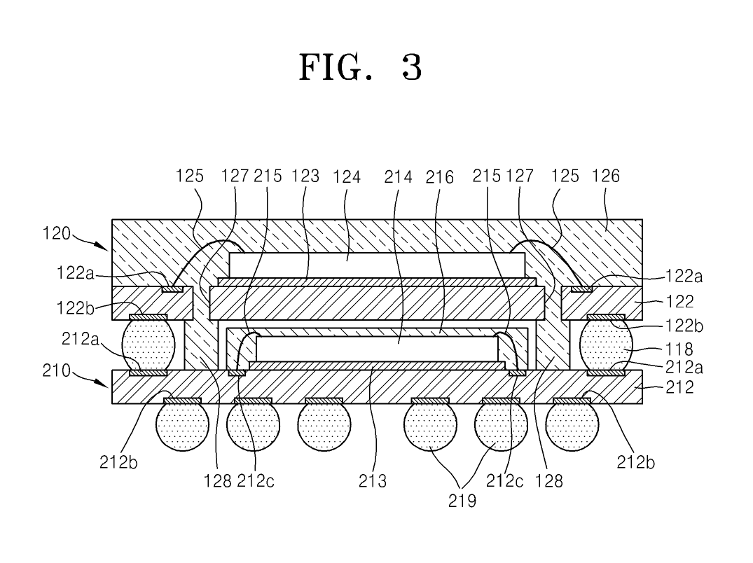

FIG. 3 is a vertical cross-sectional view illustrating a structure of a POP semiconductor package according to another exemplary embodiment.

Referring to FIG. 3, in the POP semiconductor package, a first semiconductor package 210 may have a structure in which a first semiconductor chip 214 is mounted on a first substrate 212 by a wire bonding manner, and a second semiconductor package 120 stacked on the first semiconductor package 210 may also have a structure in which a second semiconductor chip 124 is mounted on a second substrate 122 by a wire bonding manner. That is, while the first semiconductor package 210 has the structure different from that of the first semiconductor package 110 of FIGS. 1A and 1B, which is a flip chip type, the second semiconductor package 120 is the same as that illustrated in FIGS. 1A and 1B. Thus, hereinafter, the detailed description regarding the second semiconductor package 120 is omitted, and only the first semiconductor package 210 will be described.

In the first semiconductor package 210, the first semiconductor chip 214 is mounted on the first substrate 212 by the wire bonding manner. In more detail, the first semiconductor chip 214 may be adhered on the first substrate 212 with an adhering layer 213. A plurality of bonding pads 212c are arranged on a top surface of the first substrate 212, and the first substrate 212 may be electrically connected to the first semiconductor chip 214 with a wire 215 that connects the first semiconductor chip 214 and each of the bonding pads 212c. The first semiconductor chip 214, the wire 215, and the bonding pads 212c may be covered and protected by an upper molding layer 216. The upper molding layer 216 of the first semiconductor package 210 may be formed of an EMC, as the upper molding layer 126 of the second semiconductor package 120.

A plurality of connection pads 212a are arranged on the top surface of the first substrate 212 so as to electrically connect to the second semiconductor package 120 via inner solder balls 118 adhered to the connection pads 212a, respectively. The connection pads 212a may be arranged in a single row or rows having a predetermined distance from both edges of the first semiconductor chip 214. A plurality of connection pads 212b may be arranged on a bottom surface of the first substrate 212 so as to connect to an external substrate (not shown), and outer solder balls 219 may be adhered to the connection pads 212b, respectively.

When the second semiconductor package 120 is coupled to the first semiconductor package 210 having the aforementioned structure, spacers 128 that project from a bottom surface of the second substrate 122 of the second semiconductor package 120 contact the top surface of the first substrate 212, so that the spacers 128 firmly support the first substrate 212 and the second substrate 122 and maintain a gap between the first substrate 212 and the second substrate 122. Thus, it is possible to obtain the same effect as that of the embodiment of FIGS. 1A and 1B.

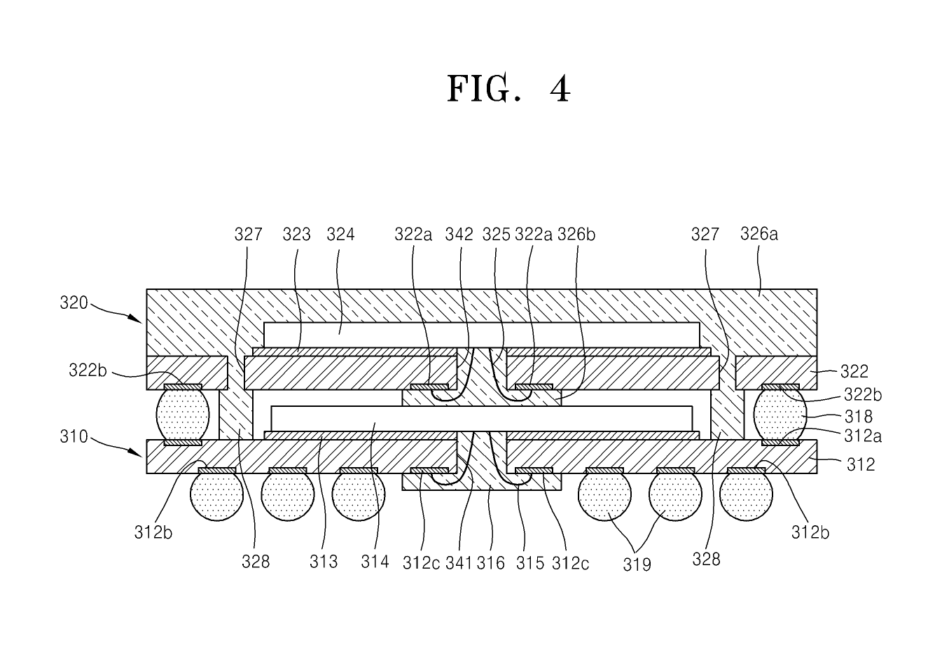

FIG. 4 is a vertical cross-sectional view illustrating a structure of a POP semiconductor package according to another exemplary embodiment.

Referring to FIG. 4, in the POP semiconductor package, a first semiconductor package 310 may have a structure in which a first semiconductor chip 314 is mounted on a first substrate 312 by a wire bonding manner, and a second semiconductor package 320 stacked on the first semiconductor package 310 may also have a structure in which a second semiconductor chip 324 is mounted on a second substrate 322 by a wire bonding manner.

However, structures of the first semiconductor package 310 and the second semiconductor package 320 of FIG. 4 are different from those of the first semiconductor package 210 and the second semiconductor package 120 of FIG. 3.

In the first semiconductor package 310, the first semiconductor chip 314 is mounted on the first substrate 312 by the wire bonding manner. In more detail, the first semiconductor chip 314 may be adhered on a top surface of the first substrate 312 with an adhering layer 313. A hole, or slit 341 may be vertically formed in a middle portion of the first substrate 312 and the adhering layer 313, and on a bottom surface of the first substrate 312, a plurality of bonding pads 312c may be arranged along sides of the slit 341. The first semiconductor chip 314 may be connected to each of the bonding pads 312c with a wire 315 that passes through the slit 341, and by doing so, the first substrate 312 and the first semiconductor chip 314 may be electrically connected to each other. The wire 315 and the bonding pads 312c may be covered and protected by a lower molding layer 316.

A plurality of connection pads 312a are arranged on the top surface of the first substrate 312 so as to electrically connect to the second semiconductor package 320 via inner solder balls 318 adhered to the connection pads 312a, respectively. The connection pads 312a may be arranged in a single row or rows having a predetermined distance from both edges of the first semiconductor chip 314. A plurality of connection pads 312b may be arranged on the bottom surface of the first substrate 312 so as to connect to an external substrate, and outer solder balls 319 may be adhered to the connection pads 312b, respectively.

In the second semiconductor package 320, the second semiconductor chip 324 is mounted on the second substrate 322 by the wire bonding manner. In more detail, the second semiconductor chip 324 may be adhered on a top surface of the second substrate 322 with an adhering layer 323. A hole, or slit 342 that penetrates vertically through the second semiconductor package 320 may be formed in a middle portion of the second substrate 322, and on a bottom surface of the second substrate 322, a plurality of bonding pads 322a may be arranged along sides of the slit 342. The second semiconductor chip 324 may be connected to each of the bonding pads 322a with a wire 325 that passes through the slit 342, and by doing so, the second substrate 322 and the second semiconductor chip 324 may be electrically connected to each other. A plurality of connection pads 322b are arranged on the bottom surface of the second substrate 322 so as to electrically connect to the first semiconductor package 310. The connection pads 322b are arranged facing the connection pads 312a that are arranged on the top surface of the first substrate 312 of the first semiconductor package 310, so that the connection pads 322b contact the inner solder balls 318.

The second semiconductor chip 324 may be covered and protected by an upper molding layer 326a, and the wire 325 and the bonding pads 322a may be covered and protected by a lower molding layer 326b.

In the second semiconductor package 320, a plurality of spacers 328 that project may be formed on the bottom surface of the second substrate 322. The spacers 328 may be formed of an EMC, which is the same material for forming the upper molding layer 326a, and may be connected to the upper molding layer 326a via through holes 327 that are formed vertically penetrating the second substrate 322. The spacers 328 function to support the first substrate 312 and the second substrate 322 and maintain a gap between the first substrate 312 and the second substrate 322 when the second semiconductor package 320 is coupled on the first semiconductor package 310.

In this manner, the function of the spacers 328 is the same as that of the spacers 128 illustrated in FIGS. 1A, 1B, and 2, and the effect thereof is also the same, so that the detailed description thereof is omitted here. Also, a height, shape, forming method, and the disposition of the spacers 328 may be the same as those of the spacers 128 illustrated in FIGS. 1A, 1B, and 2, and thus the detailed descriptions thereof are omitted here as well.

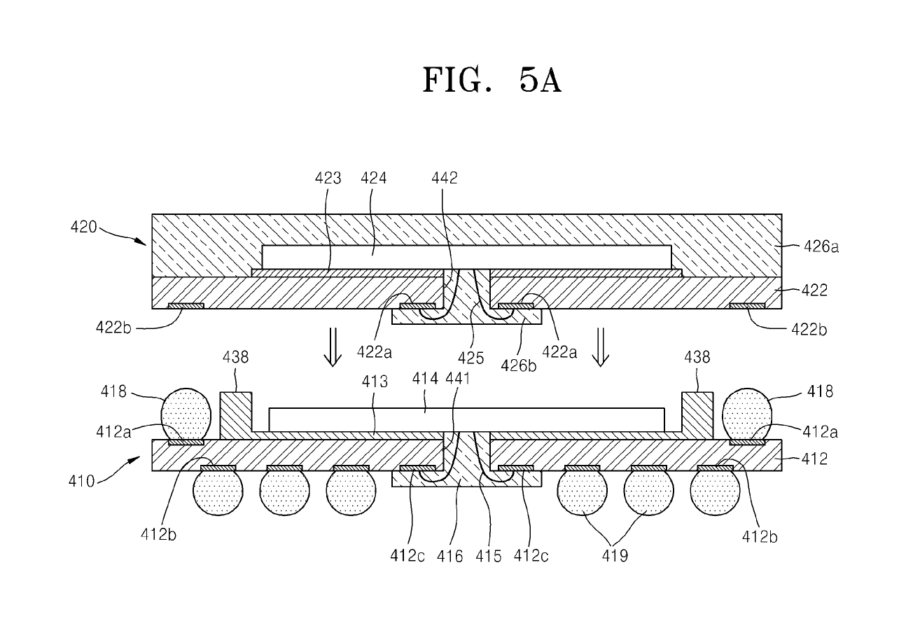

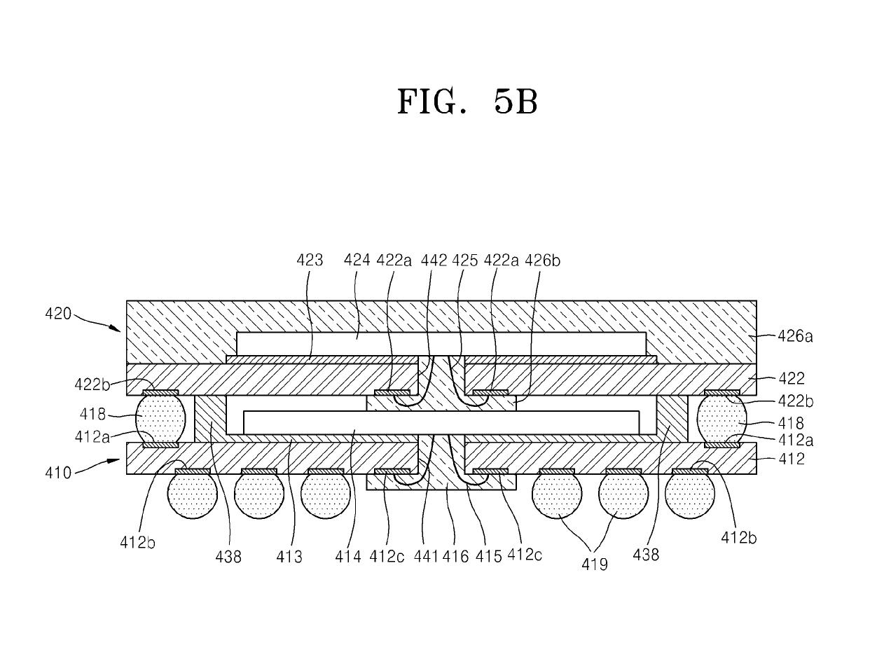

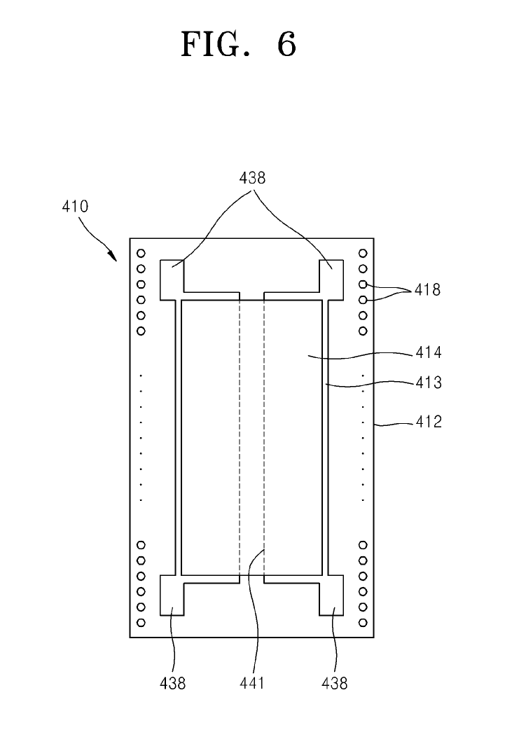

FIGS. 5A and 5B are vertical cross-sectional views illustrating a structure of a POP semiconductor package according to another exemplary embodiment. FIG. 5A illustrates a status before a first semiconductor package 410 and a second semiconductor package 420 are coupled to each other, and FIG. 5B illustrates a status after the first semiconductor package 410 and the second semiconductor package 420 are coupled to each other. FIG. 6 is an exemplary plane view of the first semiconductor package 410, which illustrates the disposition of spacers 438 of FIGS. 5A and 5B, according to one exemplary embodiment.

Referring to FIGS. 5A and 5B, the POP semiconductor package according to the present embodiment includes the first semiconductor package 410, the second semiconductor package 420 stacked on the first semiconductor package 410, and the spacers 438 disposed between the first semiconductor package 410 and the second semiconductor package 420.

In the first semiconductor package 410, a first semiconductor chip 414 may be mounted on a first substrate 412 by a wire bonding manner. In more detail, the first semiconductor chip 414 may be adhered on a top surface of the first substrate 412 with an adhering layer 413. A hole, or slit 441 that penetrates vertically through the first semiconductor package 410 may be formed in a middle portion of the first substrate 412, and on a bottom surface of the first substrate 412, a plurality of bonding pads 412c may be arranged along sides of the slit 441. The first semiconductor chip 414 may be connected to each of the bonding pads 412c with a wire 415 that passes through the slit 441, and by doing so, the first substrate 412 and the first semiconductor chip 414 may be electrically connected to each other. The wire 415 and the bonding pads 412c may be covered and protected by a lower molding layer 416.

A plurality of connection pads 412a are arranged on the top surface of the first substrate 412 so as to electrically connect to the second semiconductor package 420 via inner solder balls 418 adhered to the connection pads 412a, respectively. The connection pads 412a may be arranged in a single row or rows having a predetermined distance from both edges of the first semiconductor chip 414. A plurality of connection pads 412b may be arranged on the bottom surface of the first substrate 412 so as to connect to an external substrate, and outer solder balls 419 may be adhered to the connection pads 412b, respectively.

In the second semiconductor package 420, the second semiconductor chip 424 may be mounted on the second substrate 422 by the wire bonding manner. In more detail, the second semiconductor chip 424 may be adhered on a top surface of the second substrate 422 with an adhering layer 423. A slit 442 that penetrates vertically through second semiconductor package 420 may be formed in a middle portion of the second substrate 422, and on a bottom surface of the second substrate 422, a plurality of bonding pads 422a may be arranged along sides of the slit 442. The second semiconductor chip 424 may be connected to each of the bonding pads 422a with a wire 425 that passes through the slit 442, and by doing so, the second substrate 422 and the second semiconductor chip 424 may be electrically connected to each other. In one embodiment, a plurality of connection pads 422b are arranged on the bottom surface of the second substrate 422 so as to electrically connect to the first semiconductor package 410. The connection pads 422b are arranged facing the connection pads 412a that are arranged on the top surface of the first substrate 412 of the first semiconductor package 410, so that the connection pads 422b contact the inner solder balls 418.

The second semiconductor chip 424 may be covered and protected by an upper molding layer 426a, and the wire 425 and the bonding pads 422a may be covered and protected by a lower molding layer 426b.

The spacers 438 may project from the top surface of the first substrate 412 of the first semiconductor package 410 toward the second substrate 422, and thus may extend from the top surface of the first substrate 412 to a bottom surface of the second substrate 422. The spacers 438 function to maintain a gap between the first substrate 412 and the second substrate 422 when the second semiconductor package 420 is coupled on the first semiconductor package 410. Thus, the spacers 438 have a height corresponding to a desired gap between the first substrate 412 and the second substrate 422. In more detail, the spacers 438 may have a height that is slightly greater than the sum of heights of the adhering layer 413 and the first semiconductor chip 414. In one embodiment, the spacers 438 may have a columnar shape, such as a quadrangular-column shape. However, the spacers 438 may have a circular-column shape or one of various column shapes other than the quadrangular-column shape.

In one embodiment, the spacers 438 may be formed of the same material as the adhering layer 413 interposed between the first substrate 412 and the first semiconductor chip 414. For example, the spacers 438 may be formed of an epoxy-based thermocurable adhering material. In one embodiment, the adhering layer 413 (and spacers 348) material is a non-electrically-conductive material, and the spacers 438 do not electrically connect to any circuitry on either of the first or second substrates 412 and 422. The spacers 438 may be connected to the adhering layer 413 on the top surface of the first substrate 412. In one embodiment, the adhering layer 413 is formed by screen-printing the epoxy-based thermocurable adhering material 413 on the top surface of the first substrate 412, and in one embodiment, the spacers 438 may be formed together with the adhering layer 413. In more detail, a first opening corresponding to the adhering layer 413, and second openings corresponding to the spacers 438 are formed in a mask that is used in a screen-printing operation, and then a mesh of the second openings is adjusted to be less than the first opening so that the amount of the adhering material inserted via the second openings increases, compared to the amount of the adhering material inserted via the first opening. By doing so, it is possible to form the spacers 438 having the height that is greater than that of the adhering layer 413.

Referring to FIG. 6, the spacers 438 may be disposed to be adjacent to four corners of the second semiconductor chip 414, respectively, and may be disposed such that inner solder balls 418 are located between the spacers 438 and an edge of the second substrate 412. However, the disposition of the spacers 438 of FIG. 6 are only one example. That is, the spacers 438 may be disposed at various positions which are appropriate to maintain the gap between the first substrate 412 and the second substrate 422 so as to resist deformation due to a bending of the first semiconductor package 410 and the second semiconductor package 420.

Referring back to FIG. 5B, when the second semiconductor package 420 is coupled on the first semiconductor package 410, the connection pads 422b that are arranged on the bottom surface of the second substrate 422 of the second semiconductor package 420 contact the inner solder balls 418, so that the connection pads 422b are electrically connected to the bonding pads 422a that are arranged on the top surface of the first substrate 412. In this manner, the first semiconductor package 410 and the second semiconductor package 420 are physically coupled and electrically connected to each other by the inner solder balls 418 formed therebetween.

When the second semiconductor package 420 is coupled on the first semiconductor package 410, the spacers 438 contact the bottom surface of the second substrate 422, so that the spacers 428 firmly support the first substrate 412 and the second substrate 422 and maintain the gap between the first substrate 412 and the second substrate 422. Thus, it is possible to prevent the first semiconductor package 410 and the second semiconductor package 420 from being bent due to that the first semiconductor package 410 and the second semiconductor package 420 are affected by hardening or heating during or after a POP semiconductor package manufacturing process, so that it is possible to prevent the inner solder balls 418, which are disposed between the first substrate 412 and the second substrate 422, from being pressed and then deformed. By doing so, it is possible to prevent a short due to contact between the inner solder balls 418 that are adjacent to each other.

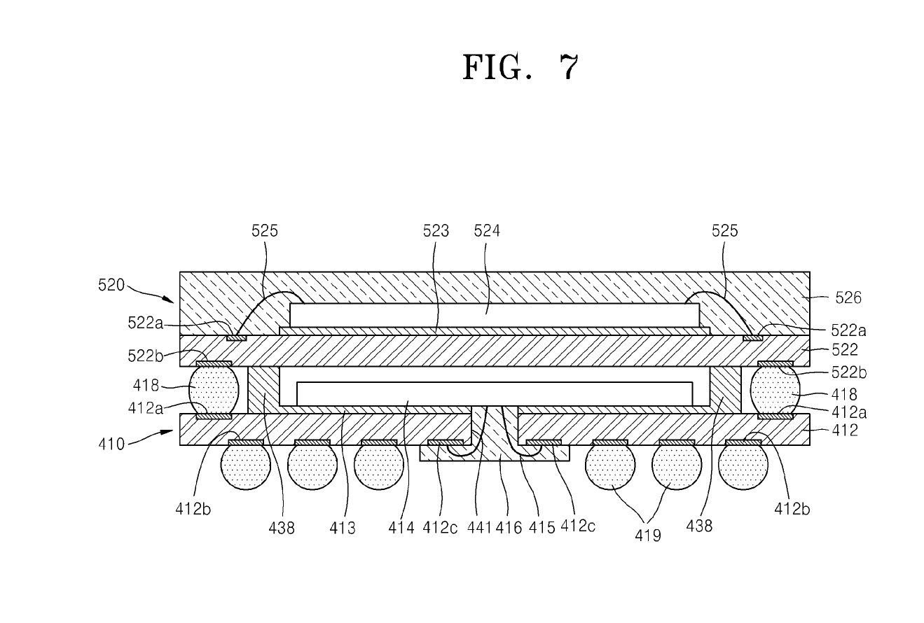

FIG. 7 is a vertical cross-sectional view illustrating a structure of a POP semiconductor package according to another exemplary embodiment.

Referring to FIG. 7, in the POP semiconductor package, a first semiconductor package 410 and a second semiconductor package 520 are a wire bonding type. However, their structures may be different from each other. That is, in one embodiment, the structure of the first semiconductor package 410 may be the same as that illustrated in FIGS. 5A and 5B, while the structure of the second semiconductor package 520 is different from a structure of the second semiconductor package 420 of FIGS. 5A and 5B which is a wire bonding type. Thus, hereinafter, the detailed description regarding the first semiconductor package 410 is omitted, and only the second semiconductor package 520 will be described.

In the second semiconductor package 520, a second semiconductor chip 524 may be adhered on a top surface of a second substrate 522 with an adhering layer 523. A plurality of bonding pads 522a are arranged on the top surface of a second substrate 522, and the second substrate 522 may be electrically connected to the second semiconductor chip 524 with a wire 525 that connects the second semiconductor chip 524 and each of the bonding pads 522a. The second semiconductor chip 524, the wire 525, and the bonding pads 522a may be covered and protected by an upper molding layer 526. A plurality of connection pads 522b are arranged on a bottom surface of the second substrate 522 so as to electrically connect to the first semiconductor package 410. The connection pads 522b are arranged facing connection pads 412a that are arranged on a top surface of a first substrate 412 of the first semiconductor package 410, so that the connection pads 522b contact inner solder balls 418.

When the second semiconductor package 520 having the aforementioned structure is coupled on the first semiconductor package 410, the bottom surface of the second substrate 522 contacts spacers 438 that project from the top surface of the first substrate 412 of the first semiconductor package 410. By doing so, the first substrate 412 and the second substrate 522 may be firmly supported, and a gap therebetween may be maintained. Thus, it is possible to obtain the same effect as that of the embodiment of FIGS. 5A and 5B.

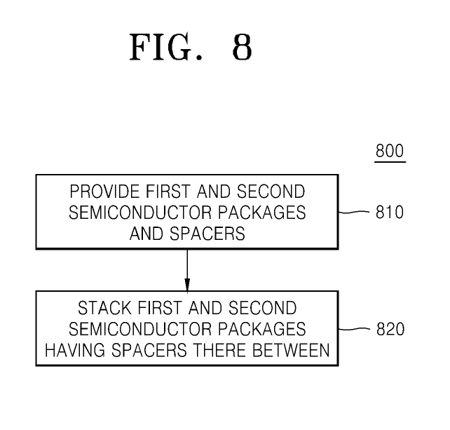

FIG. 8 depicts a method 800 of manufacturing a POP semiconductor package according to certain exemplary embodiments. As shown in FIG. 8, in a first step 810, a first semiconductor package is formed, and a second semiconductor package is formed. One of the first and second semiconductor packages may be formed, in one embodiment, to include a plurality of spacers extending therebetween.

For example, as shown in FIGS. 1A, 1B, 3, and 4, in one embodiment, a semiconductor package such as second semiconductor package 120 or 320 may include spacers that are an extension of an upper molding layer that covers the second semiconductor package and that extend past a bottom surface of a second package substrate. In one embodiment, the spacers may be created by forming a hole in the package substrate of the second semiconductor package, providing an upper mold and a lower mold that includes cavities, enclosing the second semiconductor package between the upper mold and lower mold, and then injecting a molding material between the upper mold and lower mold, as discussed previously.

As another example, as shown in FIGS. 5A, 5B, and 7, in one embodiment, a semiconductor package such as first semiconductor package 410 may include spacers that are an extension of an adhesive layer that adheres a package substrate of the first semiconductor package to a chip (or stack of chips) of the first semiconductor package and extends past a top surface of the chip (or stack of chips). In one embodiment, the spacers may be created using a masking procedure when forming the first semiconductor device, as discussed previously.

In step 820, the first semiconductor package and second semiconductor package are stacked on each other, having the spacers disposed between the two packages, to form a POP semiconductor package. In one embodiment, the spacers connect package substrates of the first and second semiconductor packages and have a length between the first and second package substrates that is the same as a height of conductive balls connecting the first and second package substrates. In this manner, the spacers provide additional support between the package substrates of the first and second semiconductor packages that prevents the substrates from bending or warping as a result of a heating process or other process, and reduces the likelihood that conductive balls connecting the first and second semiconductor packages will short.

While the disclosure has been particularly shown and described with reference to exemplary embodiments thereof, it will be understood that various changes if form and details may be made therein without departing from the spirit and scope of the following claims.

What is claimed is:

1. A Package-on-Package (POP) semiconductor package comprising:
a first semiconductor package comprising a first substrate and a first semiconductor chip that is mounted on the first substrate;
a second semiconductor package that is stacked on the first semiconductor package and that comprises a second substrate and a second semiconductor chip mounted on the second substrate; and
a plurality of spacers disposed between the first substrate and the second substrate and maintaining a gap between the first substrate and the second substrate, wherein the plurality of spacers are not electrically connected to any circuitry on the first substrate or second substrate.

2. The POP semiconductor package of claim 1, wherein a plurality of connection pads are arranged on a bottom surface of the first substrate so as to connect to an external substrate.

3. The POP semiconductor package of claim 1, wherein a plurality of connection pads are arranged on a top surface of the first substrate and a bottom surface of the second substrate so as to face each other, and a plurality of solder balls are interposed between the plurality of connection pads on the top surface of the first substrate and the plurality of connection pads on the bottom surface of the second substrate.

4. The POP semiconductor package of claim 1, wherein:
the plurality of spacers project from the bottom surface of the second substrate toward the first substrate,
an upper molding layer is formed on the second substrate so as to cover the second semiconductor chip, and
the plurality of spacers are connected to the upper molding layer via a plurality of through holes that vertically penetrate the second substrate.

5. The POP semiconductor package of claim 4, wherein the plurality of spacers and the upper molding layer comprise an epoxy molding compound (EMC).

6. The POP semiconductor package of claim 4, wherein:
the first semiconductor chip of the first semiconductor package is adhered on the top surface of the first substrate with an adhering layer;
a slit that vertically penetrates the first substrate is formed in a middle portion of the first substrate;
on a bottom surface of the first substrate, a plurality of bonding pads are arranged along sides of the slit; and
the first semiconductor chip is connected to each of the plurality of bonding pads with a wire that passes through the slit.

7. The POP semiconductor package of claim 1, wherein:
the plurality of spacers project from a top surface of the first substrate toward the second substrate,
the first semiconductor chip is adhered to the top surface of the first substrate with an adhering layer, and
the plurality of spacers comprise the same material as the adhering layer, and are connected to the adhering layer on the top surface of the first substrate.

8. The POP semiconductor package of claim 7, wherein the plurality of spacers and the adhering layer comprise an epoxy-based thermocurable adhering material.

9. The POP semiconductor package of claim 7, wherein the plurality of spacers have a height that is greater than the sum of heights of the adhering layer and the first semiconductor chip.

10. The POP semiconductor package of claim 7, wherein:
a slit that vertically penetrates the first substrate is formed in a middle portion of the first substrate;
on a bottom surface of the first substrate, a plurality of bonding pads are arranged along sides of the slit; and
the first semiconductor chip is connected to each of the plurality of bonding pads with a wire that passes through the slit.

11. A Package-on-Package (POP) semiconductor package comprising:
a first semiconductor package comprising a first substrate and a first semiconductor chip mounted on the first substrate;
a second semiconductor package stacked on the first semiconductor package and that comprises a second substrate and a second semiconductor chip mounted on the second substrate;
a plurality of balls disposed between the second substrate and the first substrate, the plurality of balls bonding and electrically connecting the first substrate to the second substrate; and
a plurality of spacers, separate from the plurality of balls, disposed between the first substrate and the second substrate and contacting both the first substrate and the second substrate.

12. The POP semiconductor package of claim 11, wherein:
the plurality of spacers include a plurality of columnar-shaped spacers extending at least the distance between a first surface of the first substrate and a first surface of the second substrate.

13. The POP semiconductor package of claim 11, further comprising:
at least one pad connected to each of the plurality of balls, but no pads connected to the plurality of spacers.

14. The POP semiconductor package of claim 11, wherein:
each of the plurality of spacers comprises a non-electrically-conductive material.

15. The POP semiconductor package of claim 11, wherein:
none of the plurality of spacers are configured to transmit signals to any circuitry.

16. The POP semiconductor package of claim 11, further comprising:
an upper molding layer covering the second substrate and the second semiconductor chip, wherein the upper molding layer is made of the same material as the plurality of spacers.

17. The POP semiconductor package of claim 16, further comprising:
a plurality of holes in the second substrate, each of the plurality of holes coinciding with a respective spacer of the plurality of spacers,
wherein each hole of the plurality of holes is filled with the same material as the plurality of spacers and the upper molding layer.

18. The POP semiconductor package of claim 17, wherein the material is a non-electrically-conductive material.

19. The POP semiconductor package of claim 11, further comprising:
an adhesive layer connecting the first substrate to the first semiconductor chip, wherein the adhesive layer is made of the same material as the plurality of spacers and is connected to the plurality of spacers.

20. The POP semiconductor package of claim 11, wherein:
the first substrate includes first edge and a second edge opposite the first edge, and a first surface extending from the first edge to the second edge in a first direction;
a first group of balls of the plurality of balls are disposed on the first surface of the first substrate proximate to the first edge;
a second group of balls of the plurality of balls are disposed on the first surface of the first substrate proximate to the second edge;
a first group of spacers of the plurality of spacers is disposed such that the first group of balls are between the first edge and the first group of spacers in the first direction; and
a second group of spacers of the plurality of spacers is disposed such that the second group of balls are between the second edge and the second group of spacers in the first direction.
